(19) United States
(12) Patent Application Publication
(10) Pub. No.: US 2010/0065943 A1
(43) Pub. Date: Mar. 18, 2010

(54) METHOD FOR INCLUDING DECOUPLING CAPACITORS INTO SEMICONDUCTOR CIRCUIT HAVING LOGIC CIRCUIT THEREIN AND SEMICONDUCTOR CIRCUIT THEREOF

(76) Inventors: Tien-Chang Chang, Hsinchu City (TW); Ming-Tzong Yang, Hsinchu County (TW); Tao Cheng, Hsinchu City (TW); Cheng-Hsing Chien, Hsinchu County (TW); Hsin-Hsin Hsiao, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/211,832

(22) Filed: Sep. 17, 2008

(51) Int. Cl. H01L 27/04

(52) U.S. Cl. 257/532; 257/E27.048

(57) ABSTRACT

A method for including decoupling capacitors into a semiconductor circuit having at least a logic circuit therein, includes: arranging a first decoupling capacitor and a second decoupling capacitor into a first area and a second area around the logic circuit respectively, wherein a gate oxide thickness of the first decoupling capacitor is different from a gate oxide thickness of the second decoupling capacitor.

### BACKGROUND OF THE INVENTION

The present invention relates to a method for including decoupling capacitors into a semiconductor circuit and the semiconductor circuit thereof, and more particularly, to a method for including decoupling capacitors into a semiconductor circuit having at least a logic circuit therein and the semiconductor circuit thereof.

Because of continuing developments of semiconductor processes, applying a low voltage design to diminish corresponding power consumption and applying transistors having a smaller form factor have become a basic requirement of circuit design. The thickness of gate oxide of semiconductor elements have been continuously reduced owing to advances in semiconductor manufacturing processes.

In a semiconductor circuit, there may be a plurality of decoupling capacitors implemented therein. The use of these decoupling capacitors is for reducing undesired circuit power noise and for solving the dynamic IR drops of the modern semiconductor circuit. In general, the circuit structures of decoupling capacitors vary under different design requirements, and one of the most common techniques is applying a MOS (metal oxide semiconductor) capacitor between two power pads of the circuit.

Please refer to FIG. 1. FIG. 1 is a block diagram illustrating a typical circuit system 100 with a decoupling capacitor 110. The decoupling capacitor 110 is utilized to protect a sub-circuit 120 from the aforementioned IR drop and noises generated from a power pad (e.g., VDD). For instance, if the decoupling capacitor 110 is a MOS capacitor, a gate of the decoupling capacitor 110 is coupled to the power pad VDD, and a source and a drain of the decoupling capacitor 110 are coupled to another power pad GND.

By applying the decoupling capacitor 110 into the circuit system 100, when an IR drop near the sub-circuit 120 occurs, the decoupling capacitor 110 can rapidly compensate the undesired IR drop to hence prevent the sub-circuit 120 from being affected. In addition, the decoupling capacitor 110 further keeps the sub-circuit 120 away from the unwanted power noise.

Conventionally all the decoupling capacitors in a semiconductor circuit comply with the same process of the semiconductor circuit, where the process is usually identical to the process of core devices within the semiconductor circuit. However, under the 0.13 um process or even more advanced semiconductor processes, using transistors of thinner gate oxide as decoupling capacitors leads to excessive leakage currents in the semiconductor circuit.

Sometimes the decoupling capacitors may occupy around 20% area or more of the semiconductor circuit; hence it is obvious that using all decoupling capacitors with advanced processes (e.g., 0.13 um process and beyond) will lead to excessive unwanted leakage current of the whole semiconductor circuit, and worsen the circuit's performance.

From these issues, it is clear that there remains considerable room for improvement of arrangements of the decoupling capacitors in semiconductor circuits.

### SUMMARY OF THE INVENTION

It is therefore one of the objectives of the present invention to provide a method for including decoupling capacitors into a semiconductor circuit having at least a logic circuits therein to reduce the unwanted leakage current, thereby solving the problems of the conventional art.

According to one embodiment of the present invention, a method for including decoupling capacitors into a semiconductor circuit having at least a logic circuits therein is disclosed. The method includes: arranging a first decoupling capacitor and a second decoupling capacitor into a first area and a second area around the logic circuit respectively, wherein a gate oxide thickness of the first decoupling capacitor is different from a gate oxide thickness of the second decoupling capacitor.

According to another embodiment of the present invention, a semiconductor circuit is disclosed. The semiconductor circuit includes: at least a logic circuit; a first decoupling capacitor arranged in a first area around the logic circuit; and a second decoupling capacitor arranged in a second area around the logic circuit, wherein a gate oxide thickness of the first decoupling capacitor is different from a gate oxide thickness of the second decoupling capacitor.

The foregoing has outlined rather broadly the features and technical advantages of the present invention in order that the detailed description of the invention that follows may be better understood. Additional features and descriptions of the present invention will be described hereinafter which form the subject of the claims of the present invention.

It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a conventional circuit system with a decoupling capacitor.

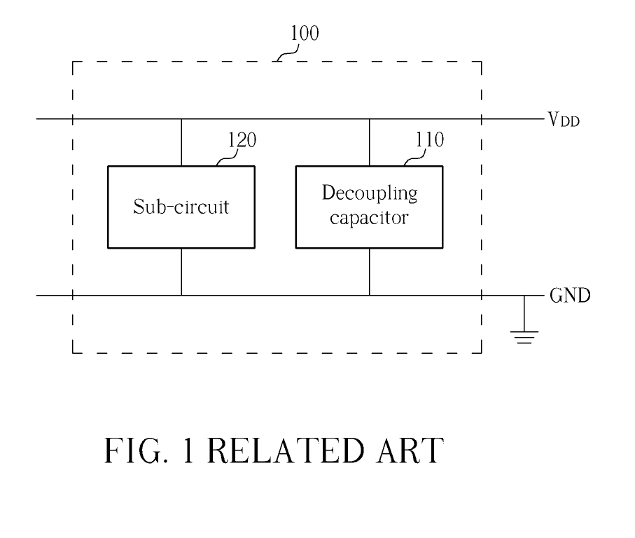

FIG. 2 is a block diagram illustrating a semiconductor circuit according to an embodiment of the present invention.

FIG. 3 is a block diagram illustrating a semiconductor circuit according to another embodiment of the present invention.

FIG. 4 is a flowchart illustrating respectively arranging first decoupling capacitor and second decoupling capacitor into the semiconductor circuit according to an embodiment of the present invention.

### DETAILED DESCRIPTION

Certain terms are used throughout the following description and claims to refer to particular system components. This document does not intend to distinguish between components that differ in name but not function. In the following discussion and in the claims, the terms “including” and “comprising” are used in an open-ended fashion, and thus should be interpreted to mean “including, but not limited to . . . .” The terms “coupled” and “couples” are intended to mean either an indirect or a direct electrical connection. Thus, if a first device couples to a second device, that connection may be through a direct electrical connection, or through an indirect electrical connection via other devices and connections.

As mentioned, an objective of the present invention is to provide a method for including decoupling capacitors into a semiconductor circuit having at least a logic circuit(s) therein, and to provide a semiconductor circuit thereof to reduce circuit power noise and improve dynamic IR drop, thereby solving the aforementioned problems of the related arts.

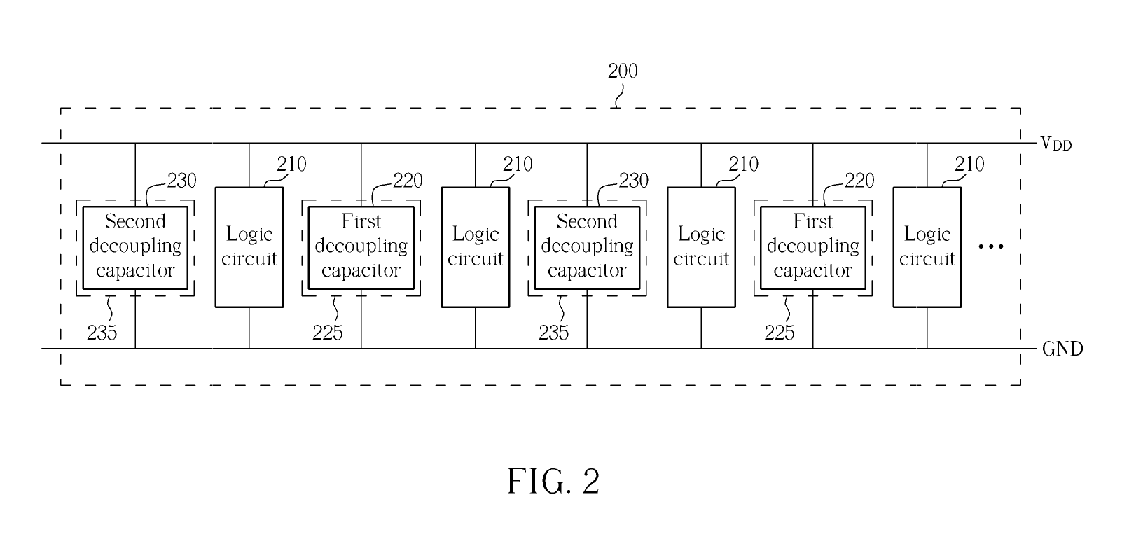

Please refer to FIG. 2. FIG. 2 is a block diagram illustrating a semiconductor circuit 200 according to an embodiment of the present invention. As shown in FIG. 2, in this embodiment, the semiconductor circuit 200 includes, but is not limited to, a plurality of logic circuits 210 (e.g., sub-circuits of the semiconductor circuit 200), at least a first decoupling capacitor 220, and at least a second decoupling capacitor 230. Wherein the first decoupling capacitors 220 are arranged into first areas 225 around the logic circuits 210 accordingly while the second decoupling capacitors 230 are arranged into second areas 235 around the logic circuits 210.

It should be noted that not only the first decoupling capacitors 220, but also the second decoupling capacitors 230 could be arranged into the first areas 225. Similarly, not only the second decoupling capacitors 230, but also the first decoupling capacitors 220 could be arranged into the second areas 235. The decoupling capacitors are not necessarily arranged into specific areas. Decoupling capacitors with different gate oxide thicknesses could be arranged into the same area. In another aspect, the first areas 225 could be viewed as where the first decoupling capacitors 220 are arranged in, while the second areas 235 could be viewed as where the second decoupling capacitors 230 are arranged in. Then not only one of the first areas 225 and the second areas 235 could be identified between or around the logic circuits 210, both of the first areas 225 and the second areas 235 could appear between or around the logic circuits 210.

In this embodiment, the semiconductor circuit 200 has decoupling capacitors with different gate oxides therein; for example, compared with the conventional semiconductor circuits (i.e., conventional integrated circuits) using decoupling capacitors with the same gate oxide, the first decoupling capacitor 220 may have a gate oxide thickness larger than the gate oxide thickness of the second decoupling capacitor 230. However, this is not meant to be a limitation of the present invention. In addition, in other embodiment, the semiconductor circuit 200 may have a logic circuit 210 with decoupling capacitors having different gate oxide thickness (e.g., first decoupling capacitor(s) 220 and second decoupling capacitor(s) 230) around the logic circuits 210.

In other embodiments, the semiconductor circuit 200 may utilize decoupling capacitors with variously different gate oxides. That is, depending upon design considerations, using decoupling capacitors with more than two different thicknesses in the semiconductor circuit 200 in FIG. 2 is feasible. The alternative design also obeys the spirit and should be considered within the scope of the present invention.

Please refer to FIG. 2; in an embodiment of the present invention, there will be spaces around the logic circuits 210 (as shown in FIG. 2). These spaces may be at least sorted into first areas 225 and second areas 235 according to the area size. In this embodiment, the larger spaces may be identified as first areas 225 and the smaller ones may be identified as the second areas 235.

Again, it should be noted that decoupling capacitors with different gate oxide thicknesses could be arranged into the same area. Not only the first decoupling capacitors 220, but also the second decoupling capacitors 230 could be arranged into the first area 225. Similarly, not only the second decoupling capacitors 230, but also the first decoupling capacitors 220 could be arranged into the second area 235. In another aspect, the first area 225 could be viewed as where the first decoupling capacitors 220 are arranged in, while the second area 235 could be viewed as where the second decoupling capacitors 230 are arranged in. Then not only one of the first area 225 and the second area 235 could be identified between or around the logic circuits 210, both of the first area 225 and the second area 235 could appear between or around the logic circuits 210. Besides, the order in which the decoupling capacitors are arranged is not limited.

In addition, since the first decoupling capacitor(s) 220 and the second decoupling capacitor(s) 230 may be used to stabilize the supply voltage of each logic circuit 210, the first decoupling capacitors 220 and the second decoupling capacitors 230 may act as filler capacitors.

In general, an I/O device (not shown) within the semiconductor circuit 200 complies with a process different from a core device within the semiconductor.

For example, elements of the I/O device in a semiconductor circuit may have thicker gate oxide than elements of the core device. As mentioned above, the first decoupling capacitors 220 may have thicker gate oxide than the gate oxide of the second decoupling capacitors 230. Therefore, the semiconductor circuit 200 can use the elements complying with the I/O device process as the first decoupling capacitors 220 and use the elements complying with the core device process as the second decoupling capacitors 230. That is, the first decoupling capacitor 220 may be made by an I/O device process, while the second decoupling capacitor 230 may be made by a core device process

Please note, however, that the above description is for illustration purposes only and is not intended as a limitation of the present invention. The selection of the first decoupling capacitors 220 and second decoupling capacitors 230 can vary under different design requirements. These alternative designs also obey the spirit and should be considered with the scope of the present invention.

During the circuit design, using decoupling capacitors with thicker gate oxide (e.g., the first decoupling capacitor 220) can diminish the undesired leakage current while may possibly cause larger dynamic IR drops at the same time. In detail, taking the implementation of using the I/O device element to realize the first decoupling capacitors 220 and using the core device elements to realize the second decoupling capacitors 230 as an example, the capacitance of the second decoupling capacitors 230 may be, for example, several times larger than the first decoupling capacitors 220, while a leakage current corresponding to the first decoupling capacitors 220 at the same time may be such as an order of five smaller than a leakage current corresponding to the second decoupling capacitors 230.

In other words, conventionally applying all the decoupling capacitors with thinner gate oxide (e.g., second decoupling capacitors 230) in the semiconductor circuit will lead to the problem of excessive leakage current. On the other hand, using all the decoupling capacitors with thicker gate oxide (e.g., first decoupling capacitors 220) into the semiconductor circuit 200 will give rise to a large undesired dynamic IR drop.

For the above reason, the semiconductor circuit 200 of the present invention applies decoupling capacitors with different gate oxides to reduce the excessive leakage current and simultaneously maintain an acceptable dynamic IR drop.

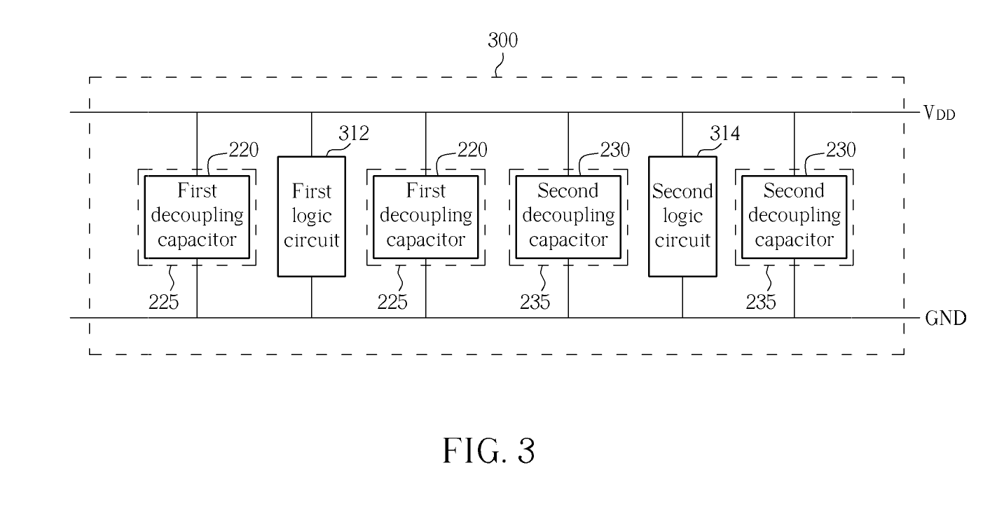

Please refer to FIG. 3; FIG. 3 is a block diagram illustrating a semiconductor circuit according to another embodiment of the present invention. As shown in FIG. 3, the semiconductor circuit 300 including a first logic circuit 312 and a second logic circuit 314, supposed that in this embodiment the performance of the first logic circuit 312 is more sensitive to the leakage than that of the second logic circuit 314, for protecting the first logic circuit 312 from being damaged, the area adjacent to the first logic circuit 312 will be determined as first area 225 (as shown in FIG. 3). In addition, the first decoupling capacitors 225, then, will be arranged in the first areas 225, wherein the gate oxide thickness of first decoupling capacitors 220 is larger than the gate oxide thickness of second decoupling capacitors 230.

In this embodiment, since the performance of the second logic circuit 314 is less sensitive to leakage current than that of the first logic circuit 312, the area around the second logic circuit 312 therefore will be determined as the second areas 235 for arranging the second decoupling capacitors 235 accordingly. Since the first decoupling capacitors 220 and the second decoupling capacitors 230 are detailed disclosed in the above description, further description is omitted for brevity.

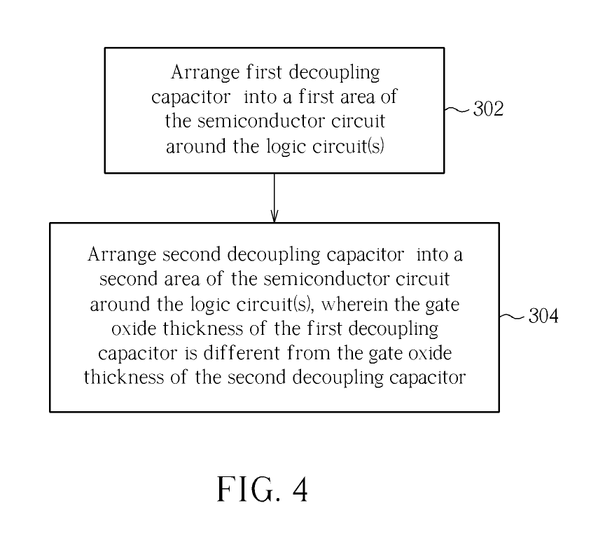

Please refer to FIG. 4 in conjunction with FIG. 2. FIG. 4 is a flowchart illustrating including first decoupling capacitors 220 and second decoupling capacitors 230 into the semiconductor circuit 200 according to an embodiment of the present invention. Please note that if the result is substantially the same, the steps are not limited to be executed according to the exact order shown in FIG. 4. The flow includes the following steps:
Step 302: Arrange a first decoupling capacitor 220 into a first area 225 of the semiconductor circuit 200 around the logic circuit(s) 210 (as shown in FIG. 2 and FIG. 3).
Step 304: Arrange a second decoupling capacitor 230 into a second area 235 of the semiconductor circuit 200 around the logic circuit(s) 210 (as shown in FIG. 2 and FIG. 3), wherein the gate oxide thickness of the first decoupling capacitor 220 is different from the gate oxide thickness of the second decoupling capacitor 230.

In other embodiments, the steps of arranging third decoupling capacitors or fourth decoupling capacitors with different gate oxides can also be incorporated into the disclosed method in FIG. 4. These alternative designs all obey the spirit of the present invention and fall within the scope of the present invention.

In this embodiment, the first area 225 is not smaller than the second area 235, and the first decoupling capacitor 220 may be arranged prior to the second decoupling capacitor 230. However, this is for illustrative purposes only, and not meant to be taken as a limitation of the present invention.

That is, in other embodiments of the present invention, the area size of the first area 225 and the second area 235 could be the same, or the first area 225 may be smaller than the second area 235. The first area 225 and the second area 235 with different sizes is for illustrative purposes only, and not meant to be taken as a limitation of the present invention.

In addition, arranging a decoupling capacitor with thicker gate oxide into a larger area available is not required to be done before arranging the decoupling capacitor with thinner gate oxide into a smaller area available. Furthermore, in other embodiment of the invention, according to different design requirement, arranging a decoupling capacitor with thicker gate oxide into a smaller area while arranging the decoupling capacitor with thinner gate oxide into a larger area applies as well.

In addition, in the present invention, since the first decoupling capacitor(s) 220 and the second decoupling capacitor(s) 230 may be used to stabilize the supply voltage of each logic circuit 210, the first decoupling capacitors 220 and the second decoupling capacitors 230 may act as filler capacitors.

Owing to an I/O device (not shown) within the semiconductor circuit 200 complies with a process different from a core device within the semiconductor, and elements of the I/O device in a semiconductor circuit (200, 300) may have thicker gate oxide than elements of the core device. The semiconductor circuit (e.g., semiconductor circuit 200, 300) in the present invention can use the elements complying with the I/O device process as the first decoupling capacitors 220 and use the elements complying with the core device process as the second decoupling capacitors 230. Since the detail of the first decoupling capacitors 220 and second decoupling capacitors 230 have been disclosed above, further description is omitted for brevity.

Furthermore, when the performance of particular logic circuit(s) (e.g., the first logic circuit 312 in FIG. 3) is more sensitive to leakage current than that of other logic circuit(s), the area that most adjacent to the particular logic circuit(s) will be accordingly determined as the first areas (e.g., first area 225). Since the related description has been disclosed above, further description is omitted here for brevity. That is, any semiconductor circuit and method thereof that employs decoupling capacitors with more than one gate oxide into the semiconductor circuit falls within the scope of the present invention.

By utilizing a plurality of decoupling capacitors of different gate oxides, an undesired dynamic IR drop is alleviated or eliminated; in addition, a circuit power noise of the semiconductor circuit is decreased simultaneously.

Briefly summarized, the present invention provides a method and semiconductor circuit thereof applying decoupling capacitors (e.g., first decoupling capacitor 220 and second decoupling capacitor 230) into one semiconductor circuit 200. Since the decoupling capacitor with thicker gate oxide (e.g., first decoupling capacitor 220) may have better leakage performance and better transient time as compared to the decoupling capacitor with thinner gate oxide (e.g., second decoupling capacitor 230), the aforementioned problems such as excessive leakage current of advanced processes are therefore solved using the exemplary semiconductor circuit design of the present invention.

It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

Those skilled in the art will readily observe that numerous modifications and alterations of the device and method may be made while retaining the teachings of the invention.

What is claimed is:

1. A method for including decoupling capacitors into a semiconductor circuit having at least a logic circuit therein, comprising:
arranging a first decoupling capacitor and a second decoupling capacitor into a first area and a second area around the logic circuit respectively, wherein a gate oxide thickness of the first decoupling capacitor is different from a gate oxide thickness of the second decoupling capacitor.

2. The method of claim 1, wherein the gate oxide thickness of the first decoupling capacitor is lager than the gate oxide thickness of the second decoupling capacitor, and the first area is not smaller than the second area.

3. The method of claim 1, wherein the first decoupling capacitor is made by an I/O device process, the second decoupling capacitor is made by a core device process, and the first area is not smaller than the second area.

4. The method of claim 1, wherein at least one of the first and second decoupling capacitors is a filler capacitor.

5. The method of claim 1, wherein the logic circuit is sensitive to leakage current, the gate oxide thickness of the first decoupling capacitor is lager than the gate oxide thickness of the second decoupling capacitor, and the first area is nearer the logic circuit than the second area.

6. A semiconductor circuit, comprising:
at least a logic circuit;
a first decoupling capacitor, arranged in a first area around the logic circuit; and
a second decoupling capacitor, arranged in a second area around the logic circuit, wherein a gate oxide thickness of the first decoupling capacitor is different from a gate oxide thickness of the second decoupling capacitor.

7. The semiconductor circuit of claim 6, wherein the gate oxide thickness of the first decoupling capacitor is larger than the gate oxide thickness of the second decoupling capacitor, and the first area is not smaller than the second area.

8. The semiconductor circuit of claim 6, wherein the first decoupling capacitor is made by an I/O device process, the second decoupling capacitor is made by a core device process, and the first area is not smaller than the second area.

9. The semiconductor circuit of claim 6, wherein at least one of the first and second decoupling capacitors is a filler capacitor.

10. The semiconductor circuit of claim 6, wherein the logic circuit is sensitive to leakage current, the gate oxide thickness of the first decoupling capacitor is lager than the gate oxide thickness of the second decoupling capacitor, and the first area is nearer the logic circuit than the second area.
